(19) United States
(12) Patent Application Publication
(10) Pub. No.: US 2026/0331435 A1
(43) Pub. Date: Oct. 22, 2026

(54) PLASMA PROCESSING APPARATUS AND SEMICONDUCTOR PROCESSING APPARATUS

(71) Applicant: Taiwan Semiconductor Manufacturing Company, Ltd., Hsinchu (TW)

(72) Inventors: Yuchien Chen, Tainan City (TW); Tzu Ken Lin, Taichung City (TW); Ching-Horng Chen, Hsinchu County (TW); Wen-Tung Chen, Taipei City (TW); Ting Hao Kuo, Hsinchu County (TW)

(73) Assignee: Taiwan Semiconductor Manufacturing Company, Ltd., Hsinchu (TW)

(21) Appl. No.: 19/186,493

(22) Filed: Apr. 22, 2025

(51) Int. Cl. H01J 37/32; H10P 72/72

(52) U.S. Cl. CPC H01J 37/32651; H01J 37/32541; H01J 37/32715; H10P 72/72; H01J 2237/332; H01J 2237/334

(57) ABSTRACT

A plasma processing apparatus includes a wafer holder, a dielectric plate and a top shield. The dielectric plate is disposed over the wafer holder. A first surface of the dielectric plate is facing to the wafer holder. The top shield, wherein includes a supporting portion and a shielding portion. The supporting portion is laterally surrounding the dielectric plate. The shielding portion is connected with the supporting portion and covering a peripheral area of the first surface. A first gap is vertically located between the shielding portion and the first surface.

### BACKGROUND

In recent years, semiconductor integrated circuits have experienced exponential growth. Advances in materials and design technologies have led to multiple generations of integrated circuits, each succeeding generation featuring smaller and more complex circuits than the previous one. As semiconductor technology has progressed, shrinking geometric dimensions (i.e., the smallest components or lines producible in the process) typically lead to increased functional density (i.e., the number of interconnected devices per chip area).

Generally, such scaling processes offer benefits such as increased production efficiency and reduced manufacturing costs. However, they also introduce greater complexity in manufacturing and producing integrated circuits. Achieving these advancements requires corresponding research and development in integrated circuit processes and manufacturing equipment. For instance, plasma processing apparatus is utilized in semiconductor device fabrication for plasma etching or plasma deposition processes. During these processes, the generation of by-products may potentially lead to contamination of semiconductor devices or the plasma processing apparatus.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view illustrating a plasma processing apparatus in accordance with some embodiments.

FIG. 2 is a cross-sectional view illustrating a plasma process utilizing the plasma processing apparatus shown in FIG. 1.

FIG. 3 is a cross-sectional view illustrating a semiconductor device resulting from the plasma process shown in FIG. 2.

FIG. 4 is a cross-sectional view illustrating a plasma processing apparatus in accordance with some embodiments.

FIG. 5 is a cross-sectional view illustrating a plasma processing apparatus in accordance with some embodiments.

FIG. 6 is a cross-sectional view illustrating a plasma processing apparatus in accordance with some embodiments.

FIG. 7 is a cross-sectional view illustrating a plasma processing apparatus in accordance with some embodiments.

FIG. 8 is a cross-sectional view illustrating a plasma processing apparatus in accordance with some embodiments.

FIG. 9 is a cross-sectional view illustrating a plasma processing apparatus in accordance with some embodiments.

FIG. 10 is a cross-sectional view illustrating a plasma processing apparatus in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

During the fabrication process of integrated circuits, a plasma processing apparatus may be used for cleaning, etching, and deposition processes, or the like. For instance, a wafer is placed into the processing space of the plasma processing apparatus, and a process gas is introduced into the processing space. The electrode of the plasma processing apparatus provide energy to the process gas (e.g., through radio frequency electromagnetic fields), ionizing gas molecules to form plasma. The ions in the plasma are used to treat the wafer. In some plasma processing apparatus, techniques such as inductively coupled plasma (ICP) or transformer coupled plasma (TCP) are employed, where the electrode of the plasma processing apparatus is separated from the plasma by dielectric material(s). For example, a dielectric plate is positioned between the electrode used to generate plasma and the processing space where plasma is formed.

During plasma processing, by-products may form in the processing space, such as polymeric materials containing Si, C, and/or O. These by-products may appear anywhere within the processing space. If these by-products become lodged in difficult-to-clean crevices (for example, narrow gaps alongside the dielectric plate), they may not be removed during the cleaning process of the processing space. Consequently, these trapped by-products have the potential to contaminate the wafers processed in the subsequent plasma process.

In some embodiments disclosed herein, to prevent contamination of the wafer by contaminants (e.g. by-products of the plasma process) around the dielectric plate (referred to as the distribution plate or the top plate in some embodiments), a shield ring (referred to as the top shield in some embodiments) is used to cover a peripheral area of the first surface of the dielectric plate facing the wafer. Therefore, even if contaminants on the sidewalls of the dielectric plate fall during the plasma process, they will only land on the shield ring and not contaminate the wafer. Additionally, to avoid affecting the uniformity of the plasma process, it is necessary to maintain a distance between the shield ring and the first surface of the dielectric plate. By separating the shield ring from the first surface of the dielectric plate, the process gas (or the plasma) may contact the entire first surface. This helps prevent the first surface from becoming uneven after the plasma process, which could otherwise decrease the uniformity of the plasma process.

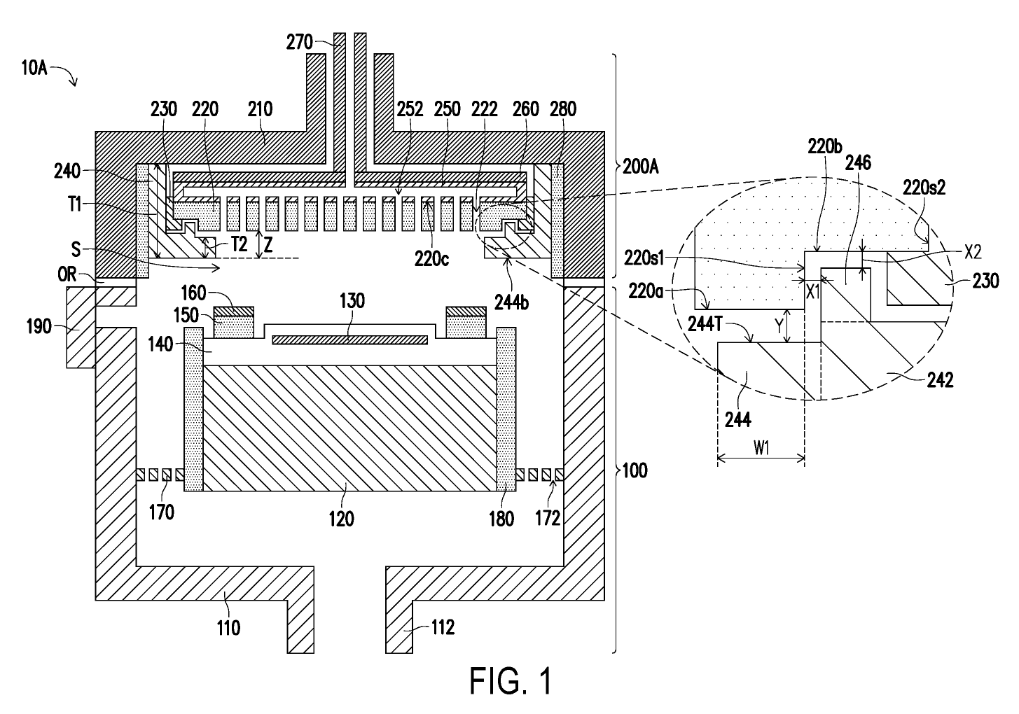

FIG. 1 is a cross-sectional view illustrating a plasma processing apparatus 10A in accordance with some embodiments. Referring to FIG. 1, the plasma processing apparatus 10A includes a lower chamber module 100 and an upper chamber module 200A. The lower chamber module 100 and the upper chamber module 200A are assembled together, and a sealing O-ring OR is included between the lower chamber module 100 and the upper chamber module 200A.

The lower chamber module 100 includes a lower outer chamber 110, a support structure 120, a first electrode 130, a wafer holder 140, an insulator 150, a ring electrode 160, a baffle 170 and a ring shield 180.

The lower outer chamber 110 may be composed of a single component or assembled from multiple components. The lower outer chamber 110 is connected to one or more gas pipes, such as an exhaust pipe 112. In some embodiments, a gate valve 190 is located outside the lower outer chamber 110, allowing wafer(s) to enter or exit the plasma processing apparatus 10A through the gate valve 190. In some embodiments, the exhaust pipe 112 is connected to a vacuum device, allowing for the extraction of gases from the processing space S and controlling the vacuum level within the processing space S.

In some embodiments, the lower outer chamber 110 includes aluminum oxide, yttrium oxide, and/or Y-O-F materials. For example, the lower outer chamber 110 is primarily made of metal, and its surface is coated with aluminum oxide, yttrium oxide, and/or Y-O-F materials. Aluminum oxide may be formed through an anodization process. By incorporating aluminum oxide, yttrium oxide, and/or Y-O-F materials on the surface of the lower outer chamber 110, interference with the plasma process may be reduced.

The support structure 120 is located inside the lower outer chamber 110. The support structure 120 may be composed of a single component or assembled from multiple components. The support structure 120 is used to support the wafer holder 140 positioned above it. In some embodiments, the wafer holder 140 comprises an electrostatic chuck (ESC), a wafer clamp, or other components capable of securing the wafer. In instances where the wafer holder 140 includes an ESC, the ESC may be energized with a DC voltage from an external power source to attract the wafer.

The first electrode 130 is embedded in the wafer holder 140. The first electrode 130 may be coupled to a radio frequency (RF) generator. During plasma processing, the first electrode 130 is biased by the RF generator to apply a bias voltage to the process gases entering the processing space S, thereby forming plasma. Additionally, the first electrode 130 may also be used to sustain the plasma.

The insulator 150 is located above the wafer holder 140. In some embodiments, the insulator 150 is ring-shaped. The insulator 150 may be composed of a single component or assembled from multiple components. The ring electrode 160 is located above the insulator 150. The wafer holder 140, the insulator 150 and the ring electrode 160 are stacked to form a capacitor. For example, the wafer holder 140 may include a lower electrode of the capacitor, while the ring electrode 160 serves as the upper electrode of the capacitor. The insulator 150 contains dielectric material and is used to isolate the upper electrode from the lower electrode. In some embodiments, the insulator 150 and the ring electrode 160 together may be referred to as a focus ring. Through the design of the insulator 150 and the ring electrode 160, the plasma generated during the plasma process may be focused more directly onto the wafer.

The ring shield 180 is surrounding the support structure 120 and the wafer holder 140. In some embodiments, the ring shield 180 includes quartz or other dielectric materials.

The baffle 170 is surrounding the ring shield 180 and the support structure 120. The baffle 170 is located between the ring shield 180 and the lower outer chamber 110. In some embodiments, the baffle 170 includes multiple exhaust holes 172 through which gases in the processing space S may exhaust towards the exhaust pipe 112, and further exit the plasma processing apparatus 10A through the exhaust pipe 112.

The upper chamber module 200A includes an upper outer chamber 210, a dielectric plate 220 (referred to as the distribution plate or the top plate in some embodiments), a plate holder 230, a shield ring 240A (referred to as the top shield in some embodiments), a diffusion plate 250, a second electrode 260, a gas inlet pipe 270, and a cover ring 280.

The upper outer chamber 210 may be composed of a single component or assembled from multiple components. The lower outer chamber 110 and the upper outer chamber 210 are assembled together, and the sealing O-ring OR is included between the lower outer chamber 110 and the upper outer chamber 210.

In some embodiments, the upper outer chamber 210 includes aluminum oxide, yttrium oxide, and/or Y-O-F materials. For example, the upper outer chamber 210 is primarily made of metal, and its surface is coated with aluminum oxide, yttrium oxide, and/or Y-O-F materials. Aluminum oxide may be formed through an anodization process. By incorporating aluminum oxide, yttrium oxide, and/or Y-O-F materials on the surface of the upper outer chamber 210, interference with the plasma process may be reduced.

In some embodiments, the upper outer chamber 210 may include a cooling system (not shown). For example, cooling pipes or a cooling chamber may be installed within the upper outer chamber 210, which may circulate cooling liquids or cooling gases.

The dielectric plate 220 is located inside the upper outer chamber 210. The dielectric plate 220 is disposed over the wafer holder 140, and the processing space S is located between the dielectric plate 220 and the wafer holder 140. The first surface 220a of the dielectric plate 220 is facing to the wafer holder 140. A plurality of through holes 222 are formed in the dielectric plate 220 and connected to the processing space S. In some embodiments, the through holes 222 are arranged in an array, giving the dielectric plate 220 a structure similar to a showerhead. This arrangement allows for the uniform delivery of process gases into the processing space S.

In some embodiments, to better secure the dielectric plate 220, a stepped structure is formed on the periphery of the dielectric plate 220. The stepped structure is formed by a first sidewall 220s1, a second surface 220b, and a second sidewall 220s2 connected sequentially. The first sidewall 220s1 is connected with a peripheral area of the first surface 220a and located between the first surface 220a and the second surface 220b. The second sidewall 220s2 is located between the second surface 220b and the third surface 220c, with the first surface 220a and the third surface 220c are respectively the front and back sides of the dielectric plate 220.

In some embodiments, the material of the dielectric plate 220 includes silicon dioxide (e.g., quartz), aluminum oxide, silicon carbide, silicon, bauxite, yttrium oxide, or the like.

The dielectric plate 220 is fixed on the plate holder 230. For example, in some embodiments, the plate holder 230 is a clamp, with the top view of the plate holder 230 being an annular shape surrounding the dielectric plate 220. The cross-sectional shape of the plate holder 230 includes a hooked structure, where the second surface 220b and the second sidewall 220s2 of the dielectric plate 220 rest against the hooked structure of the plate holder 230. In other embodiments, the dielectric plate 220 may be secured to the plate holder 230 using screws, bolts, or other fastening elements.

In some embodiments, the plate holder 230 is secured (e.g., through screws, bolts, or other fastening elements) to the shield ring 240A, the diffusion plate 250, the cover ring 280, the upper outer chamber 210, and/or other components. In other words, in the upper chamber module 200A, the dielectric plate 220 is secured to other components through the plate holder 230.

The shield ring 240A is laterally surrounding the dielectric plate 220. In some embodiments, the shield ring 240A is laterally surrounding the plate holder 230 and the dielectric plate 220. The shield ring 240A may be composed of a single component or assembled from multiple components.

In some embodiments, the shield ring 240A includes a supporting portion 242, a shielding portion 244 and an extending portion 246. The supporting portion 242 is laterally surrounding the dielectric plate 220. The shielding portion 244 is connected with the supporting portion 242 and covering a peripheral area of the first surface 220a of the dielectric plate 220. The extending portion 246 is connected with the supporting portion 242 and extends from the supporting portion 242 towards the second surface 220b of the dielectric plate 220. A thickness T1 of an outermost part (e.g. the supporting portion 242) of the shield ring 240A is greater than a thickness T2 of the innermost part (e.g. the shielding portion 244) of the shield ring 240A.

In some embodiments, the shielding portion 244 extends from the supporting portion 242 in a direction substantially parallel to the first surface 220a. The shielding portion 244 is located below the first sidewall 220s1 and the peripheral area of the first surface 220a, and a first gap Y is vertically located between a top surface 244T of the shielding portion 244 and the first surface 220a of the dielectric plate 220. A vertical distance (i.e., the width of the first gap Y) between the shielding portion 244 and the first surface 220 is greater than 0.1 mm, for example, from 0.1 mm to 3 mm.

By positioning the shielding portion 244 below the first sidewall 220s1 and the peripheral area of the first surface 220a, the shielding portion 244 may intercept contaminants (such as polymeric materials containing Si, C, and/or O) that may fall from the first surface 220a during the plasma process, thereby preventing contamination of the wafer being processed. For example, after executing a plasma process, residual process by-products may remain on the first sidewall 220s1 and be difficult to remove. During the next plasma process, these residual by-products (i.e., contaminants) could potentially drop onto the shielding portion 244, thus preventing contamination of the wafer undergoing plasma processing.

Furthermore, during plasma etching of the wafer, etching gases not only etch the wafer itself but may also etch the first surface 220a of the dielectric plate 220. Through the first gap Y between the shielding portion 244 and the first surface 220a, the etching gases may contact the entire first surface 220a, ensuring more uniform etching of the first surface 220a during the plasma etching process and reducing unevenness after etching. Unevenness on the first surface 220a could otherwise lead to uneven plasma etching of the wafer. For instance, if the shielding portion 244 were sealed against the peripheral area of the first surface 220a without the first gap Y, etching gases would contact and etch the central area of the first surface 220a but not the peripheral area, resulting in a thicker dielectric plate 220 at the peripheral area compared to the central area. Such unevenness on the first surface 220a could impair subsequent plasma processes from uniformly executing on the wafer.

In some embodiments, the shielding portion 244 overlaps the area of the first surface 220a in the form of a ring with a width W1. In some embodiments, the width W1 ranges from 3.5mm to 6.5mm. In some embodiments, the distance Z between the first surface 220a and the bottom surface of the shielding portion 244 ranges from 1.5mm to 2.5mm.

The extending portion 246 extends, for example, substantially perpendicular to the first surface 220a, from the supporting portion 242 towards the dielectric plate 220. In some embodiments, the extending portion 246 is situated between the first sidewall 220s1 and the plate holder 230. This configuration helps reduce the likelihood of process gases coming into contact with the plate holder 230, thereby decreasing interference with the plasma process and minimizing damage caused by process gases to the plate holder 230. In this embodiment, a second gap X1 is laterally located between the extending portion 246 and the first sidewall 220s1 due to manufacturing tolerances, but this disclosure is not limited thereto. In other embodiments, the extending portion 246 contacts the first sidewall 220s1. Similarly, in this embodiment, a third gap X2 is vertically located between the extending portion 246 and the second surface 220b due to manufacturing tolerances, but this disclosure is not limited thereto. In other embodiments, the extending portion 246 contacts the second surface 220b. In some embodiments, the width of the second gap X1 ranges from 0.5mm to 2.5mm. Within this range, the dielectric plate 220 is less likely to get stuck on the shield ring 240A, facilitating the removal of the dielectric plate 220.

In some embodiments, to reduce costs, different materials may be used for the shield ring 240A and the plate holder 230. For example, since the plate holder 230 is hidden inside and less exposed to process gases, a lower-cost aluminum with an aluminum oxide coating may be chosen for the plate holder 230. Conversely, because the shield ring 240A is more exposed to process gases and to minimize interference with the plasma process, materials such as yttrium oxide or yttrium oxide-coated materials may be selected for making the shield ring 240A. In some embodiments, the shield ring 240A and the plate holder 230 may also be made from the same material.

The diffusion plate 250 is located above the dielectric plate 220. In some embodiments, the dielectric plate 220 is secured (e.g., through screws, bolts, or other fastening elements) to the diffusion plate 250. The diffusion plate 250 includes a gas channel 252 that connects to the through holes 222 of the dielectric plate 220. Process gases introduced through the gas inlet pipe 270 diffuse within the gas channel 252 of the diffusion plate 250 and are further delivered through the underlying through holes 222 of the dielectric plate 220 into the processing space S. The diffusion plate 250 may be made from a conductive material such as aluminum, for example.

The second electrode 260 is located above the diffusion plate 250, with the diffusion plate 250 located between the second electrode 260 and the dielectric plate 220. The second electrode 260 may be a coil or an electrode plate. In some embodiments, a grounding voltage or a high-frequency voltage (e.g., radio frequency voltage) is supplied to the second electrode 260 via conductive springs (not shown), wires, or other conductive structures.

The cover ring 280 is surrounding the dielectric plate 220, the plate holder 230, the shield ring 240A, the diffusion plate 250 and the second electrode 260. In some embodiments, the cover ring 280 includes quartz or other dielectric materials.

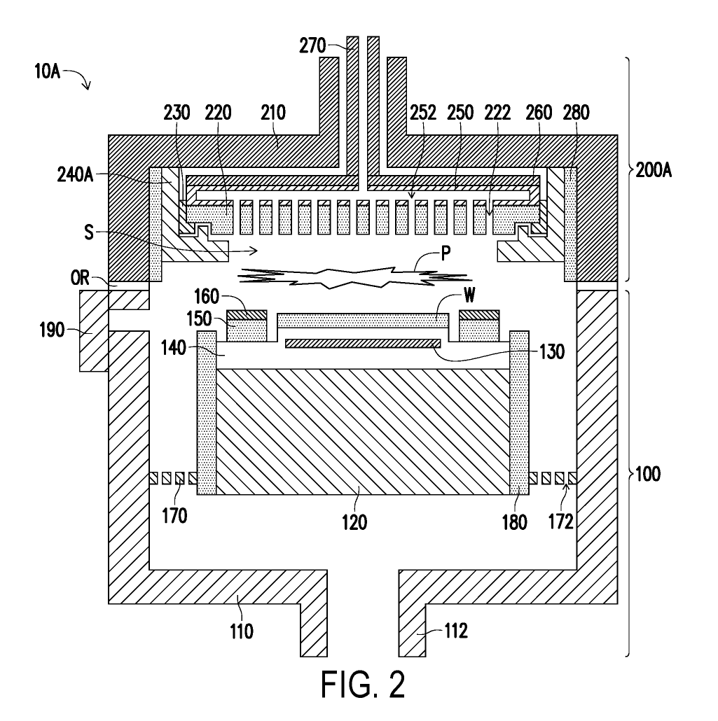

FIG. 2 is a cross-sectional view illustrating a plasma process utilizing the plasma processing apparatus 10A shown in FIG. 1. Referring to FIG. 2, the wafer W is loaded on the wafer holder 140. The wafer W may include semiconductor materials such as elemental semiconductor materials, compound semiconductor materials, alloy semiconductor materials, or other similar substances. In some embodiments, the wafer W includes integrated circuits. For example, the wafer W may be manufactured through processes such as ion doping processes, insulator deposition processes, conductor deposition processes, photolithography processes, and etching processes to form multiple dies on a semiconductor substrate. In other words, the wafer W may include multiple dies that have not yet been separated from each other.

The process gas is introduced into the processing space S, and energy is supplied to the processing gas to generate plasma P. The plasma P is used to treat the wafer W, for instance, etching, thin film deposition, or cleaning.

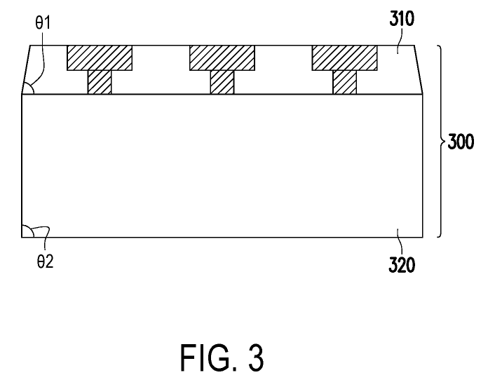

In some embodiments, the plasma processing apparatus 10A is used to perform an etching process on the wafer W to divide the wafer W into multiple dies 300. FIG. 3 illustrates the structure of one such die 300 (i.e. semiconductor device). In some embodiments, the die 300 includes a semiconductor substrate 320 and an interconnection structure 310 formed on the semiconductor substrate 320. The plasma process etches both the semiconductor substrate 320 (e.g., silicon) and the insulating layer (e.g., oxide) in the interconnection structure 310. Due to the different materials, the sidewall angle θ1 of the interconnection structure 310 formed by the plasma process is different from the sidewall angle θ2 of the semiconductor substrate 320 formed by the plasma process. In some embodiments, the angle θ1 is approximately 75 degrees to 85 degrees, while the angle θ2 is approximately 85 degrees to 90 degrees. In FIG. 3, the thickness of the semiconductor substrate 320 is greater than the thickness of the interconnection structure 310, but this disclosure is not limited thereto. In other embodiments, the thickness of the interconnection structure 310 may be greater than the thickness of the semiconductor substrate 320. For example, the thickness of the interconnection structure 310 ranges from 10 µm to 14 µm, while the thickness of the semiconductor substrate 320 ranges from 6 µm to 9 µm.

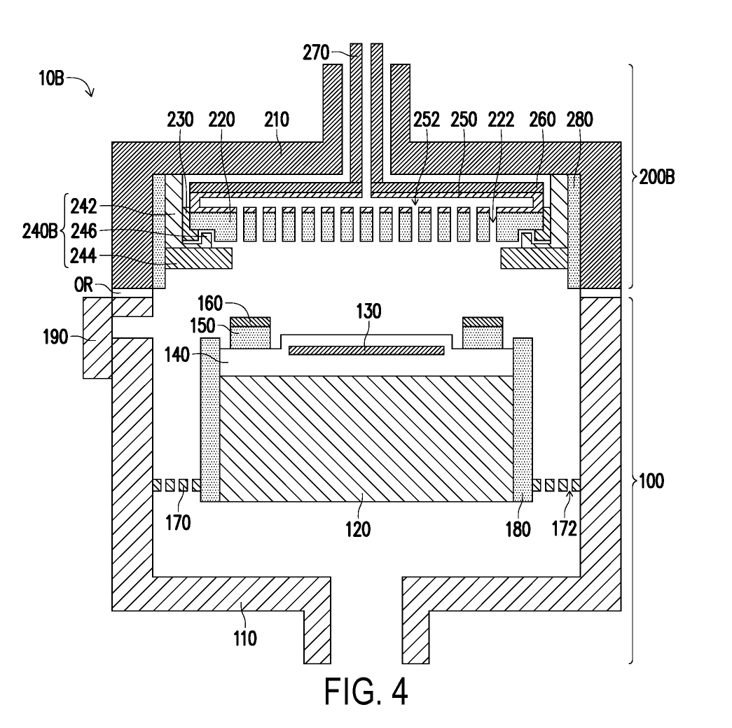

FIG. 4 is a cross-sectional view illustrating a plasma processing apparatus 10B in accordance with some embodiments. In FIG. 4, the plasma processing apparatus 10B is similar to the plasma processing apparatus 10A in FIG. 1, except that in the plasma processing apparatus 10B of FIG. 4, the shield ring 240B in the upper chamber module 200B is composed of multiple components assembled together.

Referring to FIG. 4, in this embodiment, the shield ring 240B includes a supporting portion 242, a shielding portion 244 and an extending portion 246. The supporting portion 242 is laterally surrounding the dielectric plate 220. The shielding portion 244 is connected with the supporting portion 242 and covering a peripheral area of the first surface 220a of the dielectric plate 220. The extending portion 246 is connected with the supporting portion 242 and extends from the supporting portion 242 towards the second surface 220b of the dielectric plate 220.

In this embodiment, the supporting portion 242 and the extending portion 246 are integrated as one piece, while the shielding portion 244 is an assembled component on the supporting portion 242. In some embodiments, the material of the shielding portion 244 may be the same as or different from that of the supporting portion 242 and the extending portion 246.

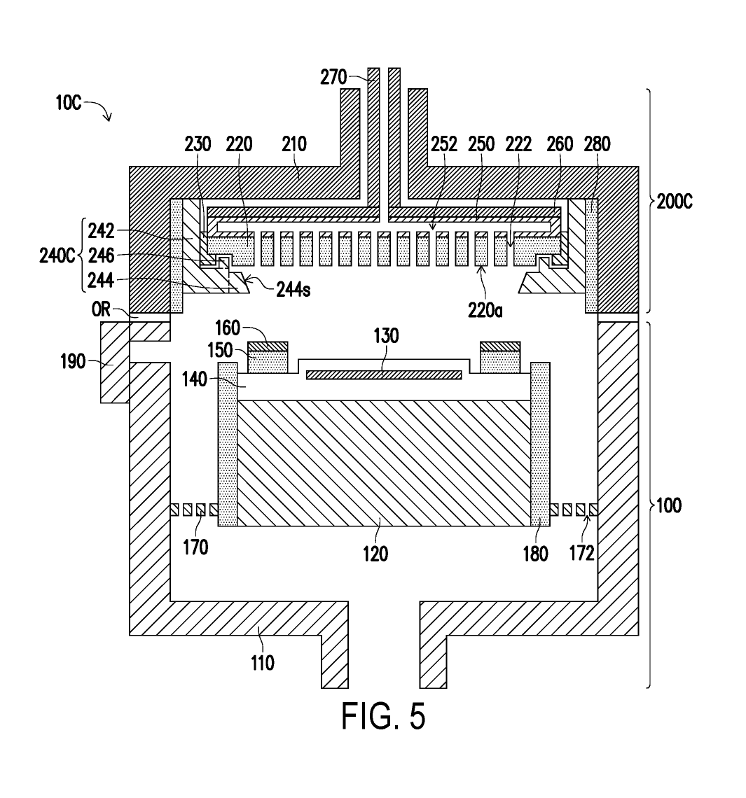

FIG. 5 is a cross-sectional view illustrating a plasma processing apparatus 10C in accordance with some embodiments. In FIG. 5, the plasma processing apparatus 10C is similar to the plasma processing apparatus 10A in FIG. 1, except that the shield ring 240C in the upper chamber module 200C in FIG. 5 has a shape different from the shield ring 240A in FIG. 1.

Referring to FIG. 5, in this embodiment, the shield ring 240C includes a supporting portion 242, a shielding portion 244 and an extending portion 246. The supporting portion 242 is laterally surrounding the dielectric plate 220. The shielding portion 244 is connected with the supporting portion 242 and covering a peripheral area of the first surface 220a of the dielectric plate 220. The extending portion 246 is connected with the supporting portion 242 and extends from the supporting portion 242 towards the second surface 220b of the dielectric plate 220.

In this embodiment, the side surface 244s of the shielding portion 244 is an inclined surface, making the side surface 244s slightly face towards the first surface 220a of the dielectric plate 220. In some embodiments, the side surface 244s of the shielding portion 244 is a curved surface.

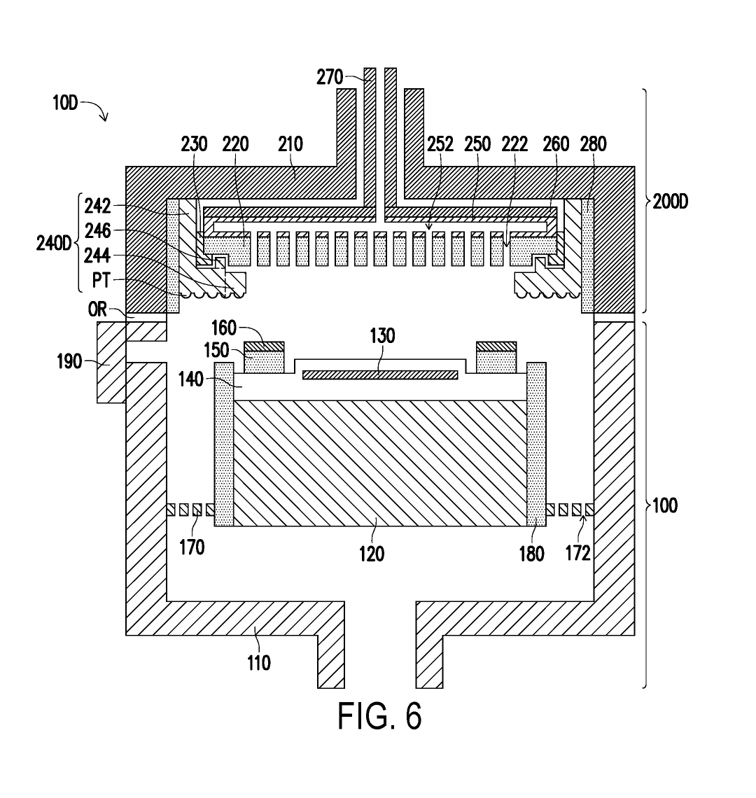

FIG. 6 is a cross-sectional view illustrating a plasma processing apparatus 10D in accordance with some embodiments. In FIG. 6, the plasma processing apparatus 10D is similar to the plasma processing apparatus 10A in FIG. 1, except that the shield ring 240D in the upper chamber module 200D in FIG. 6 has a shape different from the shield ring 240A in FIG. 1.

Referring to FIG. 6, in this embodiment, the shield ring 240D includes a supporting portion 242, a shielding portion 244 and an extending portion 246. The supporting portion 242 is laterally surrounding the dielectric plate 220. The shielding portion 244 is connected with the supporting portion 242 and covering a peripheral area of the first surface 220a of the dielectric plate 220. The extending portion 246 is connected with the supporting portion 242 and extends from the supporting portion 242 towards the second surface 220b of the dielectric plate 220.

In this embodiment, the bottom of the shield ring 240D has multiple protruding structures PT, making the bottom surface of the shield ring 240D a wavy plane.

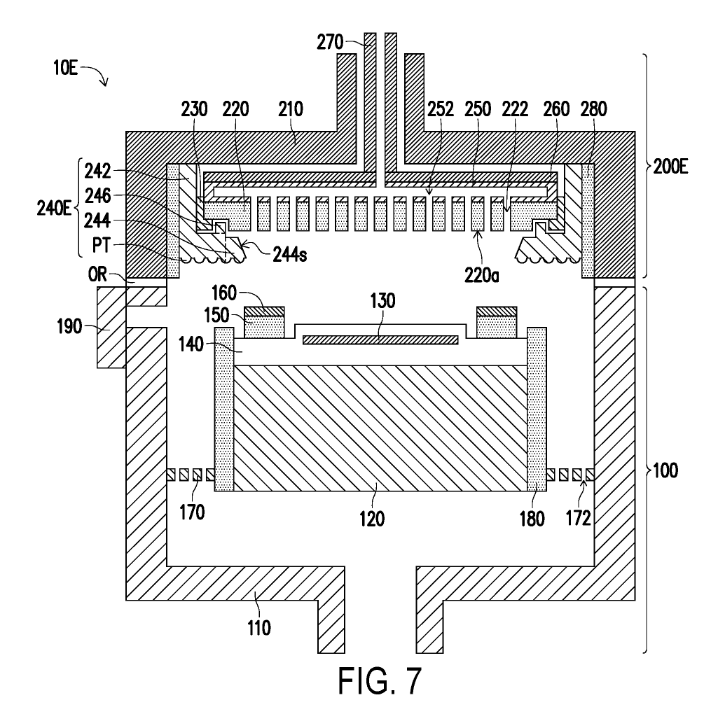

FIG. 7 is a cross-sectional view illustrating a plasma processing apparatus 10E in accordance with some embodiments. In FIG. 7, the plasma processing apparatus 10E is similar to the plasma processing apparatus 10A in FIG. 1, except that the shield ring 240E in the upper chamber module 200E in FIG. 7 has a shape different from the shield ring 240A in FIG. 1.

Referring to FIG. 7, in this embodiment, the shield ring 240E includes a supporting portion 242, a shielding portion 244 and an extending portion 246. The supporting portion 242 is laterally surrounding the dielectric plate 220. The shielding portion 244 is connected with the supporting portion 242 and covering a peripheral area of the first surface 220a of the dielectric plate 220. The extending portion 246 is connected with the supporting portion 242 and extends from the supporting portion 242 towards the second surface 220b of the dielectric plate 220.

In this embodiment, the bottom of the shield ring 240E has multiple protruding structures PT, making the bottom surface of the shield ring 240E a wavy plane. In addition, the side surface 244s of the shielding portion 244 is an inclined surface, making the side surface 244s slightly face towards the first surface 220a of the dielectric plate 220. In some embodiments, the side surface 244s of the shielding portion 244 is a curved surface.

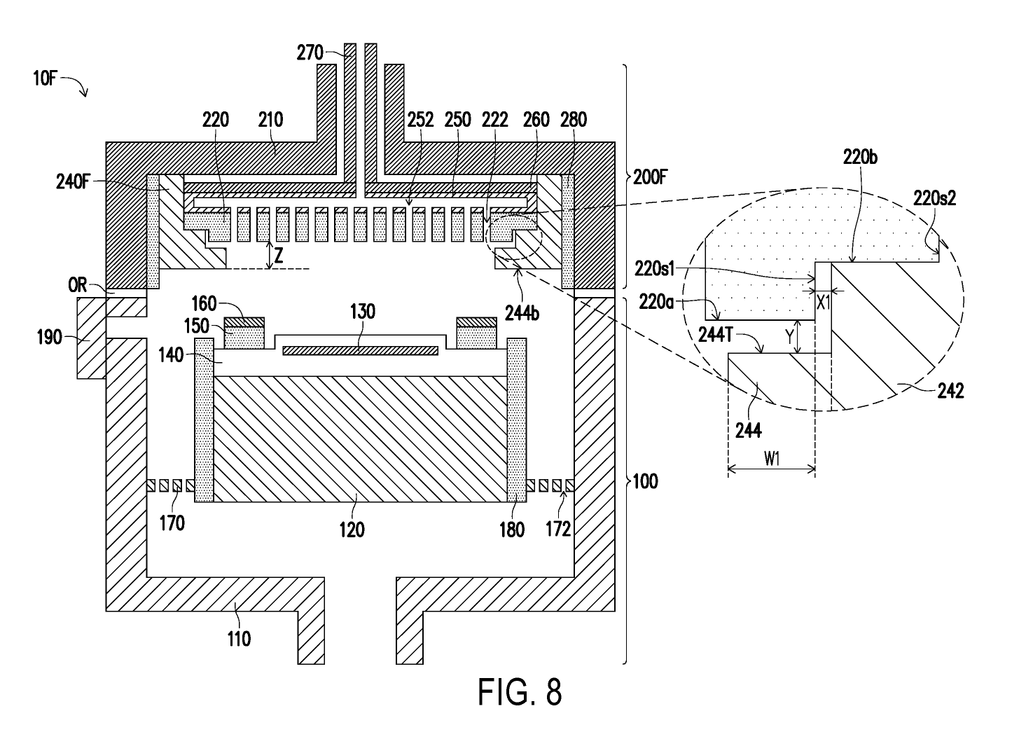

FIG. 8 is a cross-sectional view illustrating a plasma processing apparatus 10F in accordance with some embodiments. In FIG. 8, the plasma processing apparatus 10F is similar to the plasma processing apparatus 10A in FIG. 1, except that the shield ring 240F in the upper chamber module 200F in FIG. 8 has a shape different from the shield ring 240A in FIG. 1, and the upper chamber module 200F in FIG. 8 does not include the plate holder 230.

Referring to FIG. 8, in this embodiment, the shield ring 240F includes a supporting portion 242 and a shielding portion 244. The supporting portion 242 is laterally surrounding the dielectric plate 220. The shielding portion 244 is connected with the supporting portion 242 and covering a peripheral area of the first surface 220a of the dielectric plate 220.

In this embodiment, the dielectric plate 220 is fixed to the shield ring 240F. For example, the second surface 220b and/or the second sidewall 220s2 are in contact with the supporting portion 242 of the shield ring 240F.

The shielding portion 244 is located below the first sidewall 220s1 and the peripheral area of the first surface 220a, and a first gap Y is vertically located between a top surface 244T of the shielding portion 244 and the first surface 220a of the dielectric plate 220.

In this embodiment, a second gap X1 is provided between the supporting portion 242 and the first sidewall 220s1 due to manufacturing tolerances, but this disclosure is not limited thereto.

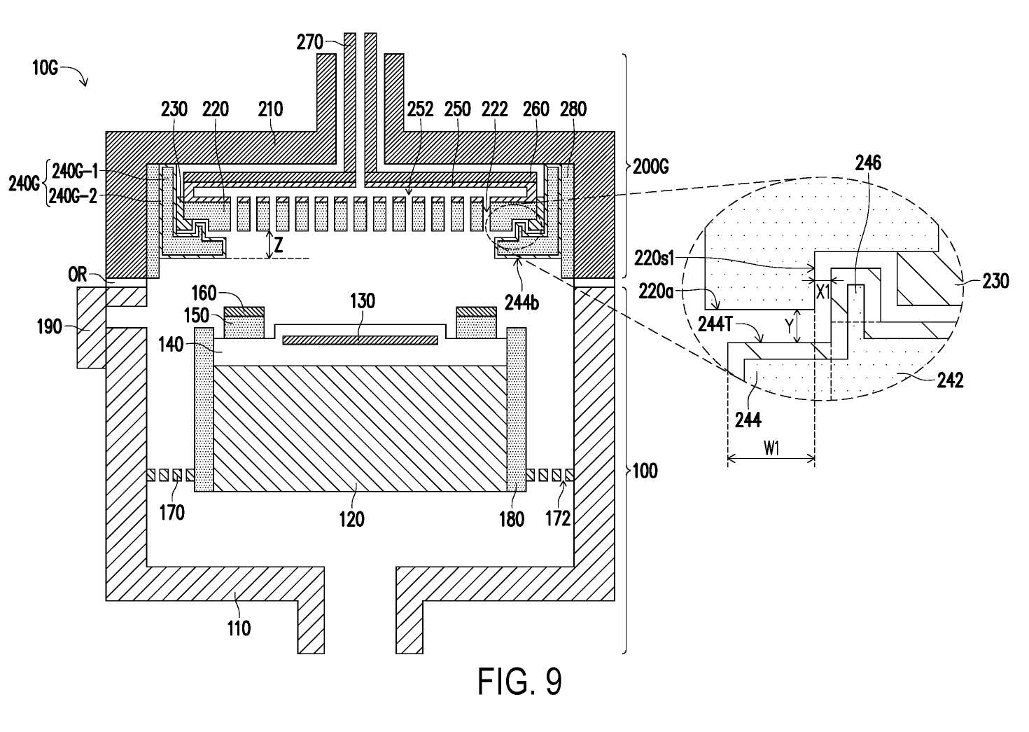

FIG. 9 is a cross-sectional view illustrating a plasma processing apparatus 10G in accordance with some embodiments. In FIG. 9, the plasma processing apparatus 10G is similar to the plasma processing apparatus 10A in FIG. 1, except that the shield ring 240G in the upper chamber module 200G in FIG. 9 has a main body 240G-1 and a protective film 240G-2 covering the outer surfaces of the main body 240G-1.

Referring to FIG. 9, in this embodiment, the shield ring 240G includes a supporting portion 242, a shielding portion 244 and an extending portion 246. The supporting portion 242 is laterally surrounding the dielectric plate 220. The shielding portion 244 is connected with the supporting portion 242 and covering a peripheral area of the first surface 220a of the dielectric plate 220. The extending portion 246 is connected with the supporting portion 242 and extends from the supporting portion 242 towards the second surface 220b of the dielectric plate 220.

In this embodiment, the shield ring 240G includes a main body 240G-1 and a protective film 240G-2. In other words, the supporting portion 242, the shielding portion 244, and the extending portion 246 each include a main body with a protective film covering their outer surfaces.

In some embodiments, the main body 240G-1 includes a metal material (such as aluminum), and the protective film 240G-2 includes a dielectric material (such as aluminum oxide, yttrium oxide, or another suitable dielectric material).

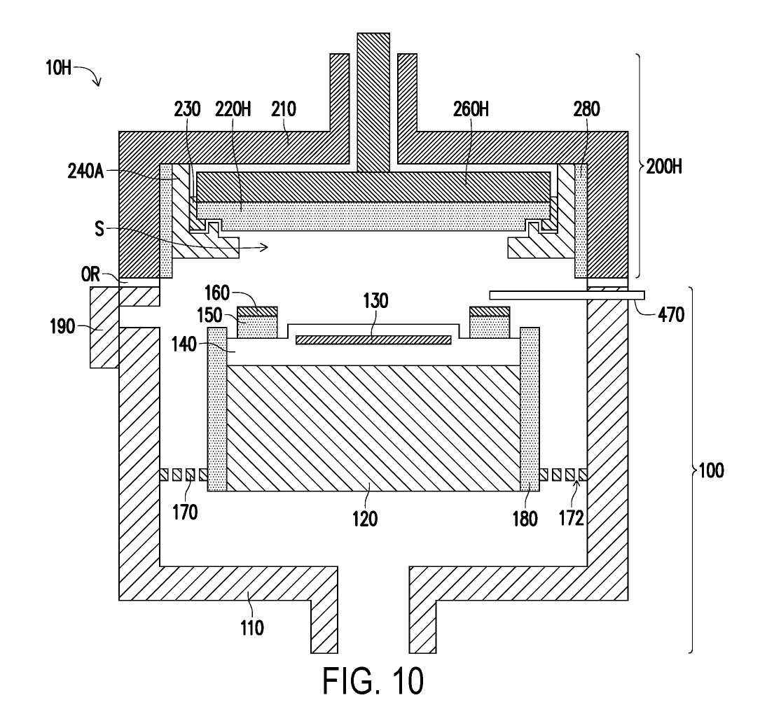

FIG. 10 is a cross-sectional view illustrating a plasma processing apparatus 10H in accordance with some embodiments. In FIG. 10, the plasma processing apparatus 10H is similar to the plasma processing apparatus 10A in FIG. 1, except that the dielectric plate 220H and the second electrode 260H in the upper chamber module 200H in FIG. 10 do not have gas channels, and the process gas does not pass through the dielectric plate 220H and the second electrode 260H into the processing space S.

Referring to FIG. 10, in this embodiment, a gas inlet pipe 470 is used to supply process gases to the processing space S. In this implementation, the gas inlet pipe 470 is integrated into the lower chamber module 100, but this disclosure is not limited thereto. In other implementations, the gas inlet pipe 470 may be integrated into the upper chamber module 200H.

Based on the above, in the disclosed embodiments, the placement of the shield ring (referred to as the top shield in some embodiments) helps prevent contaminants on the sidewalls of the dielectric plate from contaminating the wafer during plasma processing. Additionally, maintaining the first gap between the shield ring and the dielectric plate allows process gases to contact the entire first surface of the dielectric plate, thereby avoiding surface unevenness issues after the plasma process.

In accordance with some embodiments of the present disclosure, a plasma processing apparatus includes a wafer holder, a dielectric plate and a top shield. The dielectric plate is disposed over the wafer holder. A first surface of the dielectric plate is facing to the wafer holder. The top shield, wherein includes a supporting portion and a shielding portion. The supporting portion is laterally surrounding the dielectric plate. The shielding portion is connected with the supporting portion and covering a peripheral area of the first surface. A first gap is vertically located between the shielding portion and the first surface.

In accordance with some embodiments of the present disclosure, a semiconductor processing apparatus includes a chuck, a first electrode, a distribution plate, a shield ring and a diffusion plate. The first electrode is embedded in the chuck. The distribution plate is disposed over the chuck. The processing space is located between the chuck and the distribution plate, and the distribution plate includes through holes connected to the processing space. The shield ring is surrounding the distribution plate. A first gap is vertically located between the shield ring and the distribution plate. A diffusion plate is located over the distribution plate. The diffusion plate includes a gas channel connecting the through holes.

In accordance with some embodiments of the present disclosure, a plasma processing apparatus includes a wafer holder, a top plate and a shield ring. The top plate is disposed over the wafer holder. The first surface of the top plate is facing to the wafer holder. A processing space is located between the wafer holder and the top plate. A first sidewall of the top plate is connected with a peripheral area of the first surface. A shield ring is surrounding the top plate. A shielding portion of the shield ring is located below the first sidewall and the peripheral area of the first surface. A vertical distance between the shielding portion and the first surface is greater than 0.1 mm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A plasma processing apparatus, comprising:
a wafer holder;
a dielectric plate, disposed over the wafer holder, wherein a first surface of the dielectric plate is facing to the wafer holder; and
a top shield, wherein the top shield comprises:
a supporting portion, laterally surrounding the dielectric plate; and
a shielding portion, connected with the supporting portion and covering a peripheral area of the first surface, wherein a first gap is vertically located between the shielding portion and the first surface.

2. The plasma processing apparatus according to claim 1, further comprises:
a plate holder, laterally located between the top shield and the dielectric plate, wherein the dielectric plate is fixed on the plate holder.

3. The plasma processing apparatus according to claim 2, wherein the top shield comprises:
an extending portion, connected with the supporting portion, wherein the shielding portion extends from the supporting portion in a direction substantially parallel to the first surface, and the extending portion extends from the supporting portion towards the dielectric plate, wherein the dielectric plate has a stepped structure formed by a first sidewall, a second surface, and a second sidewall connected sequentially, wherein the first sidewall is located between the first surface and the second surface, and the extending portion is located between the first sidewall and the plate holder, wherein a second gap is located between the extending portion and the first sidewall.

4. The plasma processing apparatus according to claim 3, wherein a third gap is located between the extending portion and the second surface.

5. The plasma processing apparatus according to claim 1, further comprises:
an insulator, located above the wafer holder; and
a ring electrode, located above the insulator, wherein the wafer holder, the insulator and the ring electrode are stacked to form a capacitor.

6. The plasma processing apparatus according to claim 1, wherein the wafer holder comprises an electrostatic chuck, and a first electrode is embedded in the wafer holder.

7. The plasma processing apparatus according to claim 1, wherein the shielding portion comprises a main body and a protective film covering outer surfaces of the main body.

8. A semiconductor processing apparatus, comprising:
a chuck;
a first electrode, embedded in the chuck;
a distribution plate, disposed over the chuck, wherein a processing space is located between the chuck and the distribution plate, and the distribution plate comprises through holes connected to the processing space;
a shield ring, surrounding the distribution plate, wherein a first gap is vertically located between the shield ring and the distribution plate; and
a diffusion plate, located over the distribution plate, wherein the diffusion plate comprises a gas channel connecting the through holes.

9. The semiconductor processing apparatus according to claim 8, wherein the diffusion plate is made of a conductive material.

10. The semiconductor processing apparatus according to claim 8, further comprises a second electrode located above the diffusion plate, and the diffusion plate is located between the second electrode and the distribution plate.

11. The semiconductor processing apparatus according to claim 8, wherein the shield ring comprises:
a supporting portion, laterally surrounding the distribution plate; and
a shielding portion, connected with the supporting portion and covering a peripheral area of a first surface of the distribution plate, wherein the first gap is vertically located between the shielding portion and the first surface.

12. The semiconductor processing apparatus according to claim 11, further comprises:
a clamp, laterally located between the shield ring and the distribution plate, wherein the distribution plate is fixed on the clamp.

13. The semiconductor processing apparatus according to claim 12, wherein the shield ring comprises:
an extending portion, connected with the supporting portion, wherein the shielding portion extends from the supporting portion in a direction substantially parallel to the first surface, and the extending portion extends from the supporting portion towards the distribution plate, wherein the distribution plate has a stepped structure formed by a first sidewall, a second surface, and a second sidewall connected sequentially, wherein the first sidewall is located between the first surface and the second surface, and the extending portion is located between the first sidewall and the clamp, wherein a second gap is laterally located between the extending portion and the first sidewall.

14. The semiconductor processing apparatus according to claim 13, wherein the clamp is in contact with the second surface and the second sidewall.

15. The semiconductor processing apparatus according to claim 8, wherein the shield ring comprises a main body and a protective film covering the main body, wherein the protective film comprises at least one of yttrium oxide and aluminum oxide.

16. The semiconductor processing apparatus according to claim 8, wherein a width of the first gap is greater than 0.1 mm.

17. A plasma processing apparatus, comprising:
a wafer holder;
a top plate, disposed over the wafer holder, wherein a first surface of the top plate is facing to the wafer holder, wherein a processing space is located between the wafer holder and the top plate, wherein a first sidewall of the top plate is connected with a peripheral area of the first surface; and
a shield ring, surrounding the top plate, wherein a shielding portion of the shield ring is located below the first sidewall and the peripheral area of the first surface, and a vertical distance between the shielding portion and the first surface is greater than 0.1 mm.

18. The plasma processing apparatus according to claim 17, further comprises:
a clamp, laterally located between the shield ring and the top plate, wherein the top plate is fixed on the clamp.

19. The plasma processing apparatus according to claim 18, wherein the shield ring comprises:
a supporting portion, laterally surrounding the top plate;
the shielding portion, connected with the supporting portion; and
an extending portion, connected with the supporting portion, wherein the shielding portion extends from the supporting portion in a direction substantially parallel to the first surface, and the extending portion extends from the supporting portion towards the top plate, wherein the top plate has a stepped structure formed by the first sidewall, a second surface, and a second sidewall connected sequentially, wherein the first sidewall is located between the first surface and the second surface, and the extending portion is located between the first sidewall and the clamp, wherein a second gap is laterally located between the extending portion and the first sidewall.

20. The plasma processing apparatus according to claim 17, wherein a thickness of an outermost part of the shield ring is greater than a thickness of the innermost part of the shield ring, wherein the shielding portion is the innermost part of the shield ring.
